(19) United States
(12) Patent Application Publication
(10) Pub. No.: US 2018/0076403 A1
(43) Pub. Date: Mar. 15, 2018

(54) AMINE-BORANES AS ORGANIC LIGANDS FOR SURFACE FUNCTIONALIZATION

(71) Applicant: Purdue Research Foundation, West Lafayette, IN (US)

(72) Inventors: P. Veeraraghavan Ramachandran, West Lafayette, IN (US); Ameya Sanjay Kulkarni, West Lafayette, IN (US); Jianguo Mei, West Lafayette, IN (US); Yan Zhao, West Lafayette, IN (US)

(73) Assignee: Purdue Research Foundation, West Lafayette, IN (US)

(21) Appl. No.: 15/680,264

(22) Filed: Aug. 18, 2017

Related U.S. Application Data
(60) Provisional application No. 62/377,353, filed on Aug. 19, 2016.

(51) Int. Cl. H01L 51/05; B05D 1/18

(52) U.S. Cl. CPC H01L 51/0533; B05D 1/18

(57) ABSTRACT

The present invention relates to a process for functionalizing a surface of semi-conductors, conductors, and dielectrics using an amine-borane bearing a functionality from a group of, but not limited to, alkene, alkyne, hydroxyl, thiol, acetal, ester, amide, nitrile, nitro, or alkoxysilane, under a mild condition. Products of this facile process are also in the scope of this disclosure.

### CROSS-REFERENCE TO RELATED APPLICATIONS

The present U.S. patent application is related to and claims the priority benefit of U.S. Provisional Patent Application Ser. No. 62/377,353, filed Aug. 19, 2016, the contents of which are hereby incorporated by reference in their entirety into the present disclosure.

### TECHNICAL FIELD

The present invention relates to a process for functionalizing a surface of a material. In particular, it relates to a method for functionalizing the surface of semi-conductors, conductors, and dielectrics using an amine-borane bearing a functionality from a group of alkene, alkyne, hydroxyl, thiol, acetal, ester, amide, nitrile, nitro, or alkoxysilane, under a mild condition. Products of this facile process are also in the scope of this disclosure.

### BACKGROUND

This section introduces aspects that may help facilitate a better understanding of the disclosure. Accordingly, these statements are to be read in this light and are not to be understood as admissions about what is or is not prior art.

Surface modification is the act of modifying the surface of a material by bringing physical, chemical, or biological characteristics different from the ones originally found on the surface of a material. Surface modification and functionalization can also be applied to a variety of different substrates and nanoparticles for their target properties by designing appropriate chemical reactions. In recent years, novel surface functionalization techniques with diverse chemical approaches make the desired physical, thermal, electrical, and mechanical properties attainable. It is also a key step for further assembly process in order to make novel devices and materials.

Amine-boranes have gained considerable importance as potential candidates for hydrogen storage. Moreover, they have been evaluated as reagents in organic chemistry and materials chemistry. (Carboni and Monnier, Tetrahedron, 1999, 55, 1197; Staubitz, et al., Chem. Rev. 2010, 110, 4023) Amine-boranes have also shown promise as safe energetic materials. (Ramachandran et al., Chem. Eur. J. 2014, 20, 16869)

Current approaches to amine-boranes from amines include exchange with borane-Lewis base complexes or metathesis of alkylammonium salts with metal borohydrides. The former necessitates the use of moisture-sensitive and pyrophoric borane-tetrahydrofuran (BTHF) or borane-dimethyl sulfide (BMS), or harsh reaction conditions with the stable borane-ammonia complex (AB). The poor solubility of sodium borohydride and alkylammonium salts in common organic solvents severely restricts the generality of the metathesis protocol. To circumvent these, we recently discovered and disclosed a scalable protocol for amine-boranes via an in situ generation of carbonic acid from sodium bicarbonate and water (Ramachandran et al., U.S. Patent Application Publication 2016/0101984, dated Apr. 14, 2016).

Despite these advances in their synthesis and application, borane complexes of amines bearing functional groups are rare and functionalization of a material surface with those kind of amine-boranes has not been feasible.

### SUMMARY OF INVENTION

The present invention relates to a process for functionalizing a surface of semi-conductors, conductors, and dielectrics using an amine-borane bearing a functionality of, but not limited to alkene, alkyne, hydroxyl, thiol, acetal, ester, amide, nitrile, nitro, or alkoxysilane, under a mild condition. Products of this facile process are also in the scope of this disclosure.

In some illustrative embodiments, this present invention relates to a process for functionalizing a surface of a semiconductor, conductor, and dielectric material, comprising the step of exposing said surface to a solution of an amine-borane carrying a functional moiety selected from the group consisting of, but not limited to alkene, alkyne, nitro, hydroxyl, thiol, cyano (nitrile), acetal, ester, amide, and alkoxysilane.

In some other illustrative embodiments, this present invention relates to a process for functionalizing a surface of a semiconductor, conductor, and dielectric material, further comprising the step of sonication.

In some illustrative embodiments, this present invention relates to a process for functionalizing a surface of a semiconductor, conductor, and dielectric material, wherein said solution of amine-borane is an ethanol solution.

In some illustrative embodiments, this present invention relates to a process for functionalizing a surface of a semiconductor, conductor, and dielectric material, wherein said process is performed at an ambient temperature.

In some illustrative embodiments, this present invention relates to a process for functionalizing a surface of a semiconductor, conductor, and dielectric material, wherein said amine-borane is part of an aromatic molecule, an aliphatic molecule, or a combination thereof.

In some illustrative embodiments, this present invention relates to a process for functionalizing a surface of a semiconductor, conductor, and dielectric material, wherein said amine-borane is part of a cyclic structure, a linear structure, a branched structure, or a combination thereof.

In some illustrative embodiments, this present invention relates to a process for functionalizing a surface of a semiconductor, conductor, and dielectric material, wherein said functional moiety is thiol.

In some illustrative embodiments, this present invention relates to a process for preparing functionalizing a surface of a semiconductor, conductor, and dielectric material, wherein said functional moiety is hydroxyl.

In some illustrative embodiments, this present invention relates to a process for functionalizing a surface of a semiconductor, conductor, and dielectric material, wherein said functional moiety is alkoxysilane.

In some illustrative embodiments, this present invention relates to a process for functionalizing a surface of a semiconductor, conductor, and dielectric material, wherein said dielectric material can be utilized in organic field effect transistors.

In some other illustrative embodiments, this present invention relates to a semiconductor, conductor, and dielectric material, wherein surface of said material is functionalized by a process of exposing said surface to a solution of an amine-borane carrying a functional moiety selected from the group consisting of, but not limited alkene, alkyne, nitro, hydroxyl, thiol, cyano (nitrile), acetal, ester, amide, and alkoxysilane.

In some other illustrative embodiments, this present invention relates to a semiconductor, conductor, and dielectric material disclosed herein, wherein said functionalizing process further comprises a step of sonication.

In some other illustrative embodiments, this present invention relates to a semiconductor, conductor, and dielectric material disclosed herein, wherein said functionalizing process is performed at an ambient temperature.

In some other illustrative embodiments, this present invention relates to a semiconductor, conductor, and dielectric material disclosed herein, wherein said solution of an amine-borane is an ethanol solution.

### BRIEF DESCRIPTION OF FIGURES

FIG. 1A represents a topographic AFM (atomic force microscopy) image of a bare Au film. FIG. 1B represents a topographic AFM image of an amine borane functionalized Au film. FIG. 1C is a contact potential difference (CPD) map of bare Au film. FIG. 1D is a CPD map of an amine borane functionalized Au film.

FIG. 2 shows FTIR spectra of pure gold film and amine-borane modified gold film.

FIG. 3A represents an AFM image of bare SiO₂ surface. FIG. 3B represents an AFM image of APTES-borane modified SiO₂ surface (APTES: 3-Aminopropyl triethoxysilane).

FIG. 4A shows transfer characteristics of OFETs (Organic Field-Effect Transistors) using bare SiO₂/Si as substrate. FIG. 4B shows transfer characteristics of OFETs using APTES-borane modified SiO₂/Si as substrate.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure the term “about” can allow for a degree of variability in a value or range, for example, within 10%, within 5%, or within 1% of a stated value or of a stated limit of a range.

In the present disclosure the term “substantially” can allow for a degree of variability in a value or range, for example, within 80%, within 90%, within 95%, or within 99% of a stated value or of a stated limit of a range.

The present invention relates to a process for functionalizing a surface of semi-conductors, conductors, and dielectrics using an amine-borane bearing a functionality of, but not limited to alkene, alkyne, hydroxyl, thiol, acetal, ester, amide, nitrile, nitro, or alkoxysilane, under a mild condition. Products of this facile process are also in the scope of this disclosure.

In some illustrative embodiments, this present invention relates to a process for functionalizing a surface of a semiconductor, conductor, and dielectric material, comprising the step of exposing said surface to a solution of an amine-borane carrying a functional moiety selected from the group consisting of, but not limited to alkene, alkyne, nitro, hydroxyl, thiol, cyano (nitrile), acetal, ester, amide, and alkoxysilane.

In some other illustrative embodiments, this present invention relates to a process for functionalizing a surface of a semiconductor, conductor, and dielectric material, further comprising the step of sonication.

In some illustrative embodiments, this present invention relates to a process for functionalizing a surface of a semiconductor, conductor, and dielectric material, wherein said solution of amine-borane is an ethanol solution.

In some illustrative embodiments, this present invention relates to a process for functionalizing a surface of a semiconductor, conductor, and dielectric material, wherein said process is performed at an ambient temperature.

In some illustrative embodiments, this present invention relates to a process for functionalizing a surface of a semiconductor, conductor, and dielectric material, wherein said amine-borane is part of an aromatic molecule, an aliphatic molecule, or a combination thereof.

In some illustrative embodiments, this present invention relates to a process for functionalizing a surface of a semiconductor, conductor, and dielectric material, wherein said amine-borane is part of a cyclic structure, a linear structure, a branched structure, or a combination thereof.

In some illustrative embodiments, this present invention relates to a process for functionalizing a surface of a semiconductor, conductor, and dielectric material, wherein said functional moiety is thiol.

In some illustrative embodiments, this present invention relates to a process for preparing functionalizing a surface of a semiconductor, conductor, and dielectric material, wherein said functional moiety is hydroxyl.

In some illustrative embodiments, this present invention relates to a process for functionalizing a surface of a semiconductor, conductor, and dielectric material, wherein said functional moiety is alkoxysilane.

In some illustrative embodiments, this present invention relates to a process for functionalizing a surface of a semiconductor, conductor, and dielectric material, wherein said dielectric material can be utilized in organic field effect transistors.

In some other illustrative embodiments, this present invention relates to a semiconductor, conductor, and dielectric material, wherein surface of said material is functionalized by a process of exposing said surface to a solution of an amine-borane carrying a functional moiety selected from the group consisting of alkene, alkyne, nitro, hydroxyl, thiol, cyano (nitrile), acetal, ester, amide, and alkoxysilane.

In some other illustrative embodiments, this present invention relates to a semiconductor, conductor, and dielectric material disclosed herein, wherein said functionalizing process further comprises a step of sonication.

In some other illustrative embodiments, this present invention relates to a semiconductor, conductor, and dielectric material disclosed herein, wherein said functionalizing process is performed at an ambient temperature.

In some other illustrative embodiments, this present invention relates to a semiconductor, conductor, and dielectric material disclosed herein, wherein said solution of an amine-borane is an ethanol solution.

The following examples and specific embodiments are intended to illustrate the above invention and should not be construed as to narrow its scope. One skilled in the art will readily recognize that the Examples suggest many other ways in which the invention could be practiced. It should be understood that numerous variations and modifications may be made while remaining within the scope of the invention.

We recently realized an amine-ammonium salt equilibration-metathesis sequence to access amine-boranes under open-flask conditions (Scheme 1, Ramachandran, et al., Inorg. Chem. 2015, 54, 5618). Although formation of the alkylammonium sulfate intermediate occurred at ambient conditions, elevated temperatures were necessary to trans-aminate the byproduct AB formed via a competing pathway.

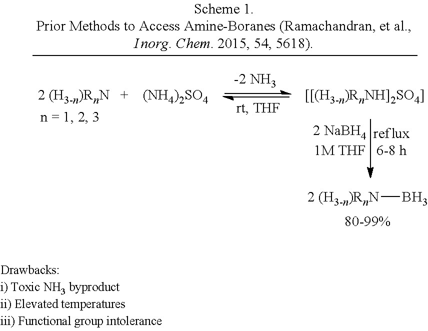

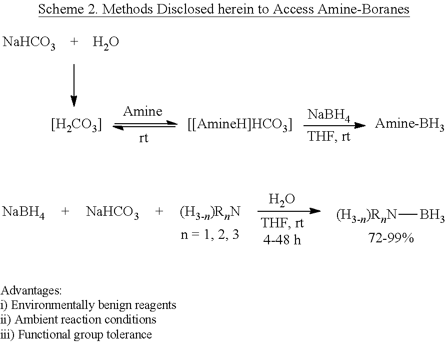

We envisaged that mild acids, such as carbonic acid, prepared from sodium bicarbonate and water, (K. Adamczyk, M. Premont-Schwarz, D. Pines, E. Pines and E. T. J. Nibbering, Science, 2009, 326, 1690), in the presence of an amine could provide alkylammonium bicarbonate in situ. This would then undergo metathesis with NaBH₄ at room temperature to provide the corresponding amine-borane (Scheme 2). Key to the success of our plan would be the capture of carbonic acid by amine prior to its ready decomposition and the stability of NaBH₄ under mildly acidic reaction conditions.

Alkenyl and alkynyl amines, with an exposed hydroboration site, were examined (Table 1). Allylamine (1q), 1,2,3,6-tetrahydropyridine (1r), and propargylamine (1s) yielded the corresponding amine-boranes 2q, 2r, and 2s in 96%, 73%, and 87%, respectively, within 4 h. Delightfully, even amines containing the protic hydroxyl moiety, such as, 2-(hydroxymethyl) pyridine (1t), 3-aminopropan-1-ol (1u), and (S)-(+)-2-(hydroxymethyl) pyrrolidine (1v), underwent borane protection yielding 2t, 2u, and 2v, respectively, in good yields after chromatographic purification. This represents the first general route to hydroxyl-containing amine-boranes from the corresponding amino alcohols.

Extending the protocol to the more acidic thiol moiety in 2-diethylaminoethanethiol (1w) provided the borane adduct 2w in high yields with a minor amount of the disulfide linked amine-borane, which could be readily separated by column chromatography. Amines containing the aldehyde and ketone functionalities were, unfortunately, not compatible and provided the reduced borane protected aminoalcohols. Dimethylaminoacetaldehyde acetal (1x), a protected aldehyde, when subjected to the reaction conditions, yielded 96% of 2x. Pleasantly, the carbonyl moiety in the ester and amide functionalities in methyl 6-aminohexanoate (1y) and N-(3-aminopropyl) benzamide (1z) was well-tolerated, furnishing 2y and 2z in 84% and 86% yields, respectively. The nitrile group in 3-(dimethylamino)propanenitrile (1aa) also remained unaltered under the reaction conditions providing the corresponding amine-borane 2aa in 86% yield. Neither the nitrile-borane nor nitrile reduction products were observed.

TABLE 1
Scope of Functionalized Amines^{a}

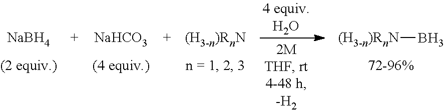

| | |
|---|---|
| 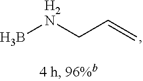 | 2q |
| 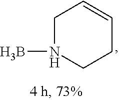 | 2r |
| 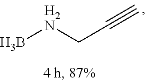 | 2s |
| 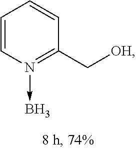 | 2t |
| 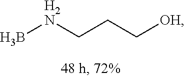 | 2u |
| 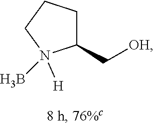 | 2v |
| 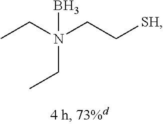 | 2w |
| 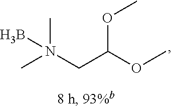 | 2x |
| 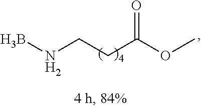 | 2y |
| 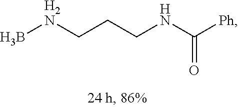 | 2z |
| 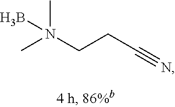 | 2aa |
| 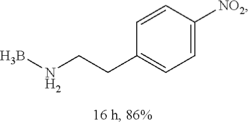 | 2ab |
| 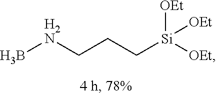 | 2ac |

^{a}Yields of isolated product. ^{b}1.5 equiv. NaBH₄, 3 equiv. NaHCO₃, and 3 equiv. water were used for 1 equiv. of amine. ^{c}Diastereomeric ratio = 92:8 (by ¹¹B NMR spectroscopy). ^{d}20% disulfide containing amine-borane was formed.

Finally, we subjected 2-(4-nitrophenyl)ethylamine (1ab), an amine containing a nitro group, to our protocol, which underwent facile borane protection to yield 2ab in 86% yield. Notably, the amine-boranes synthesized above represent stable molecules containing potentially incompatible electrophilic and nucleophilic centers in proximity.

The uniqueness of our robust and mild protocol was demonstrated by the facile synthesis of the vitronectin inhibitor synthon 4 (Scheme 3). The presence of the protic hydroxyl group was an impediment to its ready synthesis earlier. Our NaHCO₃/water-mediated protocol described herein provides a direct route to 4 in 80% yield from pyridinylamino alcohol 3 via the selective protection of the pyridine ring. The ready access to functionalized amine-boranes offered a new class of unexplored, reactive reagents for surface functionalization.

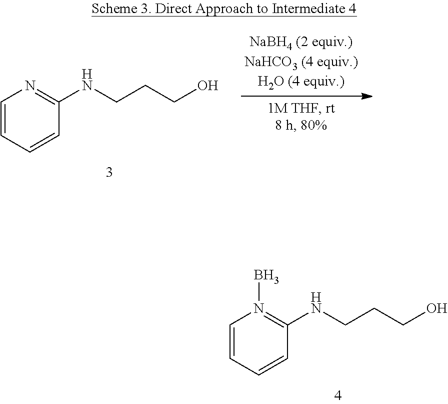

Novel amine-borane-functionalized surfaces, in turn, would deliver tailored materials possessing several unique properties. They (i) will be responsive towards an acid, (ii) can be patterned through selective removal of borane, and (iii) provide a reducing surface, potentially useful for protective coatings. To demonstrate that amine-boranes can be viable ligands for surface functionalization, the thiol bearing amine-borane 2w was chosen to functionalize gold, which is widely used as an electrode in organic electronics (Scheme 4).

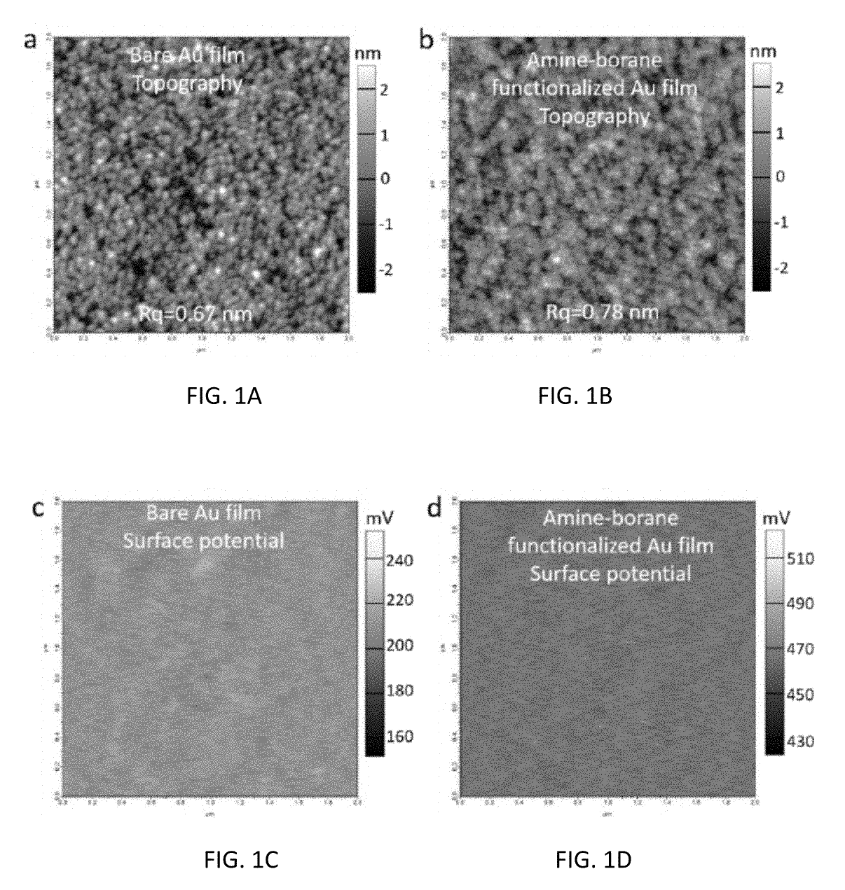

A 30 nm gold film thermally evaporated on a SiO₂/Si substrate was immersed into a solution of 2w in ethanol (10 mmol/L) for 3 h, followed by sonication and drying under nitrogen. Topographic images of the amine-borane-treated gold film revealed a surface with root mean square roughness (Rq) of ˜0.78 nm, compared to a different topography for bare gold film with Rq˜0.67 nm. (FIG. 1A and FIG. 1B). The surface potential mapping displayed a uniform surface potential (FIG. 1C and FIG. 1D). The calculated work function for amine-borane functionalized gold films and bare gold were 4.73 eV and 5.02 eV, respectively, indicating a successful surface modification. The relatively high work function of gold and the associated energy level mismatch prevents its use for n-type organic semiconducting materials. The lowering of gold work function with amine-borane treatment provides an opportunity to overcome the above limitation.

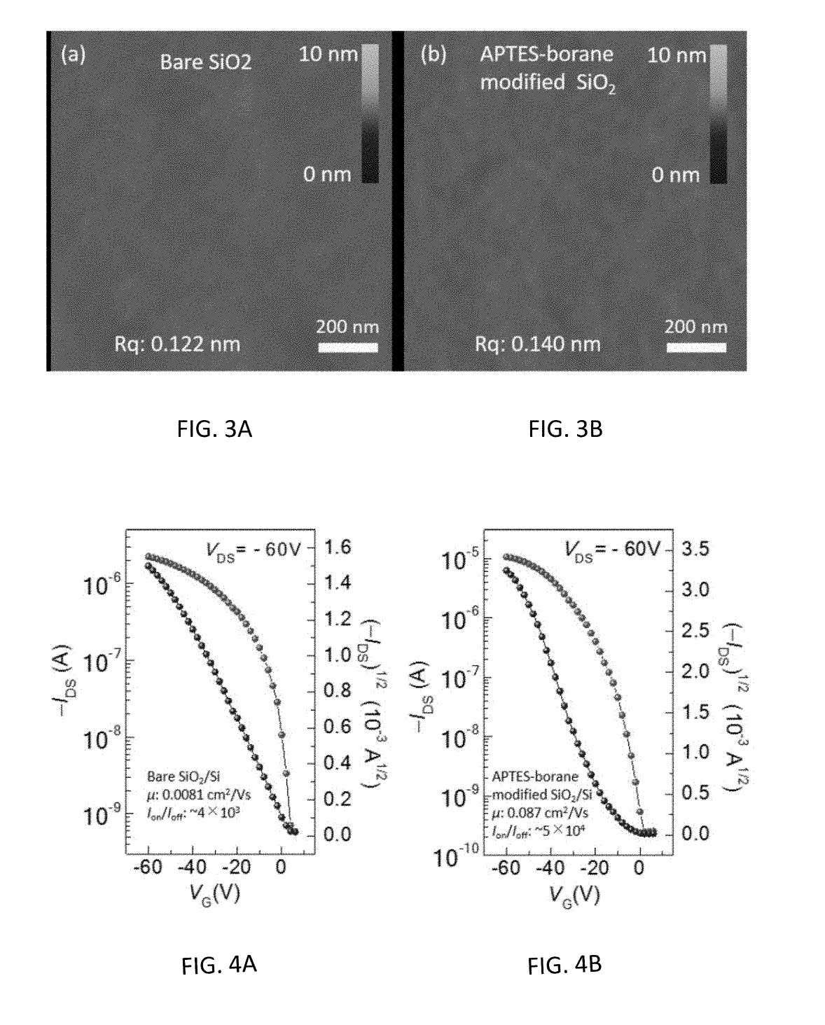

Success with gold functionalization prompted the functionalization of silica, one of the most popular dielectric materials. Silica surfaces tethered with (3-aminopropyl) triethoxysilane (APTES) have been previously reported with applications ranging from drug delivery to biomolecular lab-on-a-chip (Acres, et al., J. Phys. Chem. C, 2012, 116, 6289). Accordingly, a novel amineborane-modified silica surface was prepared by treatment with APTES-borane complex (APTES-BH₃, 2ac, Scheme 5), which was readily accessed from APTES using our protocol in 78% yield. Atomic force microscopy measurements showed smooth topography for the amine-borane-functionalized silica surface with Rq˜0.140 nm, similar to the bare silica surface (Rq˜0.122 nm, FIG. 3A and FIG. 3B). Since the hydroxyl groups on bare silica surface function as electronic traps for transport of charge carriers in organic field-effect transistors (OFETs) (Chua, et al., Nature, 2005, 434, 194) functionalization of silica surface with APTES-borane layer should principally reduce the traps, thereby improving the mobility of charge carriers. We fabricated such OFETs with the APTES-borane functionalized SiO₂/Si as the dielectric layer, providing charge carrier mobility 10× that of devices with bare silica, as well as an improved current on/off ratio (FIG. 4A and FIG. 4B).

In conclusion, a general, convenient, inexpensive, and scalable protocol for the synthesis of a variety of amine-boranes in excellent yields from sodium borohydride, sodium bicarbonate, and amines in wet THF has been developed. Under these environmentally benign, mild reaction conditions, several functional groups susceptible to BTHF or BMS, such as alkene, alkyne, hydroxyl, thiol, ester, amide, nitrile, and nitro are well tolerated. Some of these functionalized amine-boranes represent stable molecules bearing potentially incompatible electrophilic and nucleophilic groups in proximity. This water-promoted synthesis has allowed access to a novel class of amine-borane based organic ligands with unique properties for surface functionalization, as demonstrated by the formation of self-assembled layers of thiol- and alkoxysilane-bearing amine-boranes on gold and silica surfaces, respectively.

General Experimental Procedures

¹¹B, ¹H, and ¹³C NMR spectra were recorded at room temperature, on a Varian INOVA 300 MHz or Bruker 400 MHz NMR spectrophotometer. Chemical shifts (δ values) are reported in parts per million relative to BF₃.Et₂O for ¹¹B NMR respectively. Data are reported as: δ value, multiplicity (s=singlet, d=doublet, t=triplet, q=quartet, p=pentet, h=hextet, m=multiplet, br=broad) and integration. High Resolution Mass Spectra (HRMS) were recorded on a Thermo Electron Corporation MAT 95XP-Trap spectrometer. Thin-layer chromatography was carried out on 0.20 mm silica plates (G/UV₂₅₄) using UV light or Iodine as visualizing agent. Flash chromatography was performed using silica gel 40-63 um, 60 Å and dichloromethane-methanol mixture as eluent. Fourier transform infrared spectroscopy (FTIR) was performed using a Thermo Nicolet Nexus FTIR. Atomic force microscopy (AFM) topographic images were obtained on a Veeco Dimension 3100 AFM in tapping mode. Scanning Kelvin probe microscopy (SKPM) was performed using an Asylum Cypher ES atomic force microscope.

All solvents for routine isolation of products and chromatography were reagent-grade. Tetrahydrofuran (THF, ACS grade containing 0.004% water and 0.025% BHT) was purchased from Fisher-Scientific. Sodium borohydride (powder, purity>99% by hydride estimation1) was purchased in bulk from Dow Chemical Co. (Rohm and Haas). Sodium bicarbonate (ACS reagent, Macron) was purchased from the respective commercial source and powdered prior to use. Amines used were purchased from commercial sources. Methyl 6-aminohexanoate (1y) (Brehm and Breinbauer, Org. Biomol. Chem., 2013, 11, 4750.); N-(3-aminopropyl)benzamide (1z) (Tang and Fang, Tetrahedron Lett., 2008, 49, 6003); 3-(pyridin-2-ylamino)propanol (3) (Heckmann, et al., Angew. Chem. Int. Ed., 2007, 46, 3571) was prepared in accordance with literature reports. 2-Diethylaminoethanethiol (1w) (Bigley, et al., Biochemistry, 2015, 54, 5502); and 2-(4-nitrophenyl) ethylamine (1ab) (Maruyama, et al., U.S. Pat. No. 6,346,532 (2002)) were synthesized from their hydrochloride salts. Liquid amines were distilled while solid amines were used without any purification. The 99.99% gold pellets purchased from R.D. Mathis Company were used as evaporation material for preparation of gold films. 6,13-Bis(triisopropylsilylethynyl)pentacene was purchased from Sigma-Aldrich and used without purification.

### General Procedure for the Preparation of Functionalized Amine-Boranes (2r-2w, 2y-2z, 2ab-2ac, and 4)

Sodium borohydride (0.38 g, 10 mmol) and powdered sodium bicarbonate (1.68 g, 20 mmol) were transferred to a 50 mL dry round bottom flask, charged with a magnetic stir-bar. The corresponding amine (1r-1w, 1y-1z, 1ab-1ac, and 3, 5 mmol) was charged into the reaction flask followed by addition of reagent-grade tetrahydrofuran (2.5 mL for liquid amines/7.5 mL for solid amines) at rt. Under vigorous stirring, 2.5 mL of 14.4% v/v solution water in THF was added drop-wise to prevent excessive frothing. Reaction progress was monitored by ¹¹B NMR spectroscopy (Note: A drop of anhydrous DMSO is added to the reaction aliquot before running the ¹¹B NMR experiment). Upon completion of the reaction (4-48 h, as determined by ¹¹B NMR), the reaction contents were filtered through sodium sulfate and celite and the solid residue washed with THF. Removal of the solvent in vacuo from the filtrate yielded the corresponding crude amine-borane. The final products were purified by column chromatography using dichloromethane/methanol mixture as eluent.

Characterization of Amine-Boranes:

### Allylamine-Borane (2q)

Colorless oil. ¹H NMR (300 MHz, CDCl₃) δ (ppm): 5.95 (ddt, J=16.7, 10.3, 6.3 Hz, 1H), 5.39-5.18 (m, 2H), 4.29-3.95 (m, 2H), 3.46-3.27 (m, 2H), 2.10-0.90 (br q, BH₃); ¹³C NMR (75 MHz, CDCl₃) δ (ppm): 132.3, 119.3, 51.0; ¹¹B NMR (96 MHz, CDCl₃) δ (ppm): −19.81 (q, J=97.7 Hz). HRMS (CI) calcd for C₃H₉BN (M-H)⁺: m/z, 70.0823, found 70.0826.

### 1,2,3,6-tetrahydropyridine-borane (2r)

White solid. ¹H NMR (400 MHz, DMSO-d₆) δ (ppm): 6.10 (s, 1H), 5.84-5.70 (m, 1H), 5.69-5.53 (m, 1H), 3.35-3.14 (m, 1H), 3.11-2.79 (m, 2H), 2.52-2.36 (m, 1H), 2.30-2.16 (m, 1H), 2.10-1.90 (m, 1H), 1.80-0.80 (br q, BH₃); ¹³C NMR (101 MHz, DMSO-d₆) δ (ppm): 124.9, 123.6, 50.1, 48.3, 23.3; ¹¹B NMR (96 MHz, DMSO-d₆) δ (ppm): −14.48 (br q, J=95.0 Hz). HRMS (CI) calcd for C₅H₁₁BN (M-H)⁺: m/z, 96.0979, found 96.0976.

### Propargylamine-Borane (2s)

White solid. ¹H NMR (300 MHz, DMSO-d₆) δ (ppm): δ 5.71 (s, 2H), 3.50-2.97 (m, 3H), 1.90-0.50 (br q, BH₃); ¹³C NMR (75 MHz, DMSO-d₆) δ (ppm): 79.6, 75.5, 36.2; ¹¹B NMR (96 MHz, DMSO-d₆) δ (ppm): −18.69 (br q). HRMS (CI) calcd for C₃H₇BN (M-H)⁺: m/z, 68.0666, found 68.0669.

### 2-(Hydroxymethyl)pyridine-borane (2t)

White solid. ¹H NMR (300 MHz, CDCl₃) δ (ppm): 8.65 (d, J=5.8 Hz, 1H), 8.02-7.91 (m, 1H), 7.85-7.75 (m, 1H), 7.44-7.32 (m, 1H), 5.03 (s, 2H), 3.17 (s, 1H), 3.00-1.75 (br q, BH₃); ¹³C NMR (75 MHz, CDCl₃) δ (ppm): 158.6, 148.8, 140.0, 123.5, 123.4, 62.5; ¹¹B NMR (96 MHz, CDCl₃) δ (ppm): −15.23 (q, J=98 Hz). HRMS (CI) calcd for C₆H₉BNO (M-H)⁺: m/z, 122.0772, found 122.0772.

### 3-Aminopropan-1-ol-borane (2u)

Colorless oil. ¹H NMR (400 MHz, DMSO-d₆) δ (ppm): 5.09 (s, 2H), 4.49 (t, J=5.0 Hz, 1H), 3.40 (q, J=5.9 Hz, 2H), 2.58-2.35 (m, 2H), 1.61 (p, J=6.5 Hz, 2H), 1.70-0.80 (br q, BH₃); ¹³C NMR (101 MHz, DMSO-d₆) δ (ppm): 59.6, 46.3, 32.1; ¹¹B NMR (96 MHz, DMSO-d₆) δ (ppm): −19.59 (q, J=93.5 Hz). HRMS (CI) calcd for C₃H₁₁BNO (M-H)⁺: m/z, 88.0928, found 88.0926.

### (S)-(+)-2-(Hydroxymethyl)pyrrolidine-borane (2v)

Colorless oil. Diastereomeric ratio=92:8 (as analyzed by ¹¹B NMR spectroscopy). Major diastereomer: ¹H NMR (300 MHz, CDCl₃) δ (ppm): 4.48 (s, 1H), 4.09 (dd, J=11.6, 3.1 Hz, 1H), 3.78-3.58 (m, 1H), 3.37 (dt, J=10.3, 6.5 Hz, 1H), 3.06 (dtd, J=10.6, 7.6, 3.5 Hz, 1H), 2.98-2.68 (m, 2H), 2.11-1.72 (m, 4H), 2.10-0.80 (br q, BH₃); ¹³C NMR (75 MHz, CDCl₃) δ (ppm): 66.9, 60.2, 55.3, 27.4, 23.8; ¹¹B NMR (96 MHz, DMSO-d₆) δ (ppm): −16.43 (q, J=96.0 Hz). HRMS (CI) calcd for C₅H₁₃BNO (M-H)⁺: m/z, 114.1085, found 114.1087.

### 2-Diethylaminoethanethiol-borane (2w)

Colorless oil. ¹H NMR (400 MHz, CDCl₃) δ (ppm): 2.98-2.69 (m, 8H), 1.19 (t, J=7.3 Hz, 6H), 1.95-0.95 (br q, BH₃); ¹³C NMR (101 MHz, CDCl₃) δ (ppm): 61.9, 53.0, 18.7, 8.7; ¹¹B NMR (96 MHz, CDCl₃) δ (ppm): −13.45 (q, J=99.1, 93.3 Hz). HRMS (ESI) calcd for C₆H₁₇BNS (M-H)⁺: m/z, 146.1175, found 146.1176.

### 2,2-Dimethoxy-N,N-dimethylethylamine-borane (2x)

Colorless liquid. ¹H NMR (300 MHz, CDCl₃) δ (ppm): 4.94-4.88 (m, 1H), 3.44-3.37 (m, 6H), 2.90-2.83 (m, 2H), 2.64 (m, 6H), 2.20-1.10 (br q, BH₃); ¹³C NMR (75 MHz, CDCl₃) δ (ppm): 101.3, 65.2, 54.5, 53.0; ¹¹B NMR (96 MHz, CDCl₃) δ (ppm): −9.85 (q, J=99.0 Hz). HRMS (CI) calcd for C₆H₁₇BNO₂ (M-H)⁺: m/z, 146.1347, found 146.1345.

### Methyl 6-aminohexanoate-borane (2y)

White solid. ¹H NMR (300 MHz, CDCl₃) δ (ppm): 3.87 (s, 2H), 3.68 (s, 3H), 2.81 (p, J=7.2 Hz, 2H), 2.34 (t, J=7.3 Hz, 2H), 1.75-1.56 (m, 4H), 1.44-1.31 (m, 2H), 2.10-0.80 (br q, BH₃); ¹³C NMR (101 MHz, CDCl₃) δ (ppm): 174.2, 51.8, 48.6, 33.8, 28.7, 26.1, 24.4; ¹¹B NMR (96 MHz, CDCl₃) δ (ppm): −15.61 (q, J=98.0 Hz). HRMS (CI) calcd for C₇H₁₇BNO₂ (M-H)⁺: m/z, 158.1347, found 158.1349.

### N-(3-Aminopropyl)benzamide-borane (2z)

White solid. ¹H NMR (300 MHz, DMSO-d₆) δ (ppm): 8.53 (t, J=5.9 Hz, 1H), 7.89-7.76 (m, 2H), 7.58-7.38 (m, 3H), 5.19 (s, 2H), 3.26 (q, J=6.5 Hz, 2H), 2.56-2.36 (m, 2H), 1.74 (p, J=7.1 Hz, 2H), 1.75-0.80 (br q, BH₃); ¹³C NMR (101 MHz, DMSO-d₆) δ (ppm): 166.4, 134.4, 131.1, 128.3, 127.1, 45.4, 36.7, 28.3; ¹¹B NMR (96 MHz, DMSO-d₆) δ (ppm): −19.26 (br, BH₃). HRMS (CI) calcd for C₁₀H₁₆BN₂O (M-H)⁺: m/z, 191.1350, found 191.1348.

### 3-(Dimethylamino)propanenitrile-borane (2aa)

Colorless liquid. ¹H NMR (300 MHz, CDCl₃) δ (ppm): 3.11-2.88 (m, 4H), 2.66 (s, 6H), 2.19-0.94 (br q, BH₃); ¹³C NMR (75 MHz, CDCl₃) δ (ppm): 117.4, 59.5, 52.5, 14.2; ¹¹B NMR (96 MHz, CDCl₃) δ (ppm): −10.96 (q, J=98.6 Hz). HRMS (CI) calcd for C₅H₁₂BN₂ (M-H)⁺: m/z, 111.1088, found 111.1087.

### 2-(4-Nitrophenyl)ethylamine-borane (2ab)

White solid. ¹H NMR (400 MHz, DMSO-d₆) δ (ppm): 8.10 (d, J=8.6 Hz, 2H), 7.45 (d, J=8.4 Hz, 2H), 5.32 (s, 2H), 2.93 (dd, J=9.5, 6.4 Hz, 2H), 2.76-2.58 (m, 2H), 1.85-0.80 (br q, BH₃); ¹³C NMR (101 MHz, DMSO-d₆) δ 147.1, 146.2, 129.9, 123.6, 48.3, 33.9; ¹¹B NMR (96 MHz, DMSO-d₆) δ (ppm): −19.58 (q, J=101.7, 95.1 Hz). HRMS (ESI) calcd for C₈H₁₂BN₂O₂ (M-H)⁺: m/z, 179.0992, found 179.0992.

### (3-Aminopropyl)triethoxysilane-borane (2ac)

Colorless liquid. ¹H NMR (400 MHz, CDCl₃) δ (ppm): 3.99-3.88 (m, 2H), 3.84 (qd, J=7.0, 2.9 Hz, 6H), 2.82 (ddt, J=10.6, 6.9, 4.1 Hz, 2H), 1.76 (pd, J=7.1, 3.0 Hz, 2H), 1.24 (td, J=7.0, 2.9 Hz, 9H), 0.66 (td, J=7.8, 3.0 Hz, 2H), 2.10-1.10 (br q, BH₃); ¹³C NMR (101 MHz, CDCl₃) δ (ppm): 58.8, 50.9, 22.6, 18.4, 7.7; ¹¹B NMR (96 MHz, CDCl₃) δ (ppm): −19.95 (q, J=100.5 Hz). HRMS (ESI) calcd for C₉H₂₆BNO₃SiNa (M+Na)⁺: m/z, 257.1709, found 257.1711.

### 3-(Pyridin-2-ylamino)propan-1-ol-borane (4)

Colorless oil. ¹H NMR (300 MHz, CDCl₃) δ (ppm): 8.09 (d, J=6.2 Hz, 1H), 7.57 (t, J=9.0 Hz, 1H), 6.64 (d, J=8.8 Hz, 1H), 6.54 (t, J=6.6 Hz, 1H), 6.41 (s, 1H), 3.79 (t, J=5.9 Hz, 2H), 3.42 (q, J=6 Hz, 2H), 2.55 (s, 1H), 1.92 (p, J=6 Hz, 2H), 2.80-1.50 (br q, BH₃); ¹³C NMR (75 MHz, CDCl₃) δ (ppm): 154.6, 145.9, 139.8, 111.2, 107.2, 59.9, 39.9, 31.5; ¹¹B NMR (96 MHz, CDCl₃) δ (ppm): −17.92 (q, J=97.5, 91.7 Hz). HRMS (CI) calcd for C₈H₁₄BN₂O (M-H)⁺: m/z, 165.1194, found 165.1189.

General Procedure for Hydride Analysis of Amine-Boranes (Hydrolysis Reaction):

An aqueous solution of amine-borane (2 mmol in 1 mL H₂O) was transferred to a round bottom flask with a septum inlet fitted with a connecting tube. The connecting tube was attached to an analytical gas burette filled with CuSO₄ solution. A solution of RuCl₃ (4.2 mg, 1 mol % in 2 mL H₂O) was syringed into the vial, all at once. The hydrogen generated was measured using the analytical gas burette. The temperature of the reaction was maintained at 25° C.

Gold Surface Functionalization—Procedure and Characterization:

A gold film of 30 nm was thermally evaporated on a SiO₂/Si substrate. The gold film was then immersed into the solution of 2w in ethanol (10 mmol/L) for 3 hours, followed by sonication in ethanol. Atomic force microscopy (AFM) images of all samples showed typical gold film surface with no significant difference for samples with and without treatment with solution of 2w. Scanning Kelvin probe microscopy (SKPM) was conducted to measure the surface potential of the gold film. A Si cantilever tip coated with Pt—Ir (SCM-PIT-V2, Bruker Co.) was used in the tapping mode. The sample surface topography and contact potential difference (CPD) map between the tip and sample were measured at the same time and shown in FIG. 1A-FIG. 1D. Topographic image of bare gold (FIG. 1A) shows typical thermal evaporated gold film surface with roughness Rq around 0.67 nm. FIG. 1B exhibits different topography from bare gold film with Rq around 0.78 nm, and that difference must be raised by amine-borane modification. The very smooth CPD maps (FIG. 1C and FIG. 1D) show that the surface potential is uniform. The following equation is used to calculate the work function of the sample:

V_{CPD}=(Φₜᵢₚ−Φₛₐₘₚₗₑ)/e

Where Φₜᵢₚ is the work function of the Pt—Ir coated conducting AFM tips (5.2 eV) and Φₛₐₘₚₗₑ is the work function of the sample. The calculated work function of bare gold and thiol bearing amine-borane modified gold film is 5.02 eV and the 4.73 eV, respectively. This result shows that after thiol bearing amine-borane modification, the work function of gold film decreased by 0.29 eV.

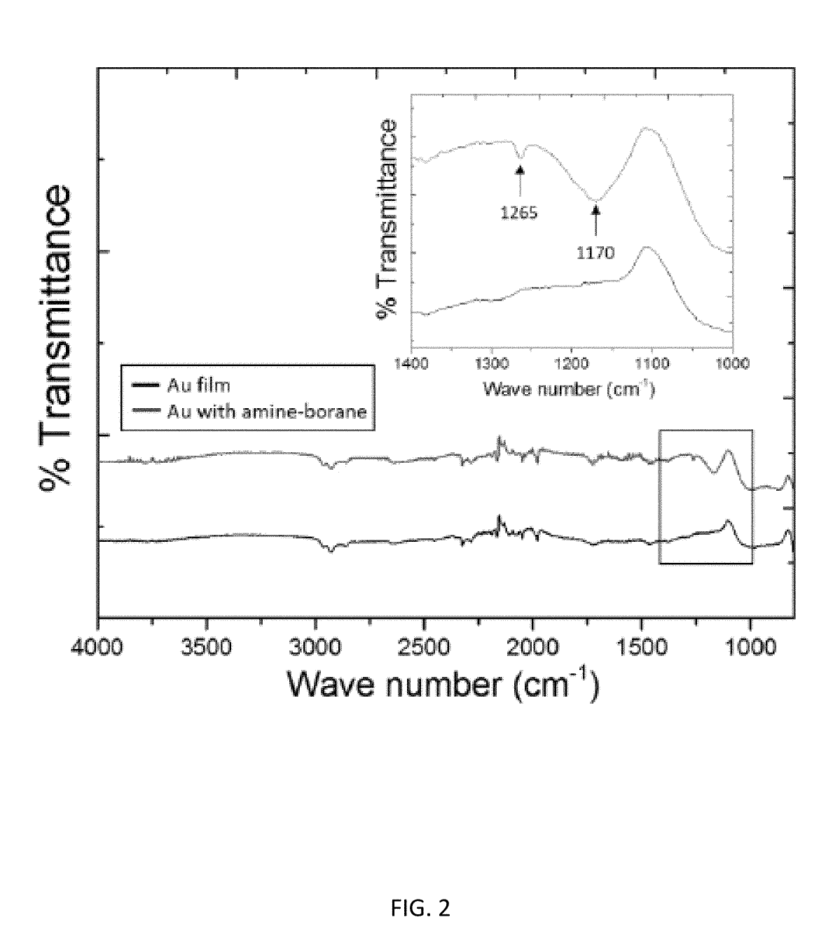

As shown in FIG. 2, comparison of FTIR spectra of Au film and Au modified with amine-borane disclosed herein revealed the successful modification of the surface of Au film demonstrated by the signature C—N stretch absorptions at 1170 cm⁻¹.

Silica Surface Modification—Procedure and Characterization:

Before APTES-borane-modification, the silica substrate was carefully cleaned by piranha solution to remove all organic residues and result in a highly hydroxylated SiO₂ surface. After successive sonication in water and ethanol followed by drying in nitrogen, the silica substrate was immersed into the solution of 2ab in ethanol (10 mmol/L) for 3 hours, followed by sonication in ethanol.

OFET Fabrication:

Bottom gate bottom contact OFETs with Bis(triisopropylsilylethynyl) pentacene as semiconductor and gold as electrodes were fabricated to verify the APTES-borane modification on SiO₂ surface. A heavily n-doped Si wafer with a 300 nm SiO₂ surface layer (capacitance of 11 nF/cm2) was employed as the substrate with Si wafer serving as the gate electrode and SiO₂ as the dielectric. The gold source and drain electrodes were sputtered and patterned by photolithography technique. The device channel width was 1000 μm and the channel length was 60 μm for all of the OFETs. Tips-Pentacene layer of 30 nm was then thermally evaporated onto both the bare and APTES-borane modified SiO₂/Si substrates. The OFETs devices were then measured using Keithley 4200 in ambient air. The field-effect mobility was calculated in the saturation regime by using the equation: I_{DS}=(μWCi/2 L)(V_{G}−V_{T})2, where I_{DS} is the drain-source current, μ is the field-effect mobility, W is the channel width, L is the channel length, Ci is the capacitance per unit area of the gate dielectric layer, V_{G} is the gate voltage, and V_{T} is the threshold voltage.

Those skilled in the art will recognize that numerous modifications can be made to the specific implementations described above. The implementations should not be limited to the particular limitations described. Other implementations may be possible.

What is claimed is:

1. A method for functionalizing a surface of a semiconductor, conductor, and dielectric material, comprising the step of exposing said surface to a solution of an amine-borane carrying a functional moiety selected from the group consisting of alkene, alkyne, nitro, hydroxyl, thiol, cyano (nitrile), acetal, ester, amide, and alkoxysilane.

2. The method of claim 1, further comprising a step of sonication.

3. The method of claim 1, wherein said solution of an amine-borane is ethanol.

4. The method of claim 1, wherein said functional moiety is thiol.

5. The method of claim 1, wherein said functional moiety is hydroxyl.

6. The method of claim 1, wherein said functional moiety is alkoxysilane.

7. The method of claim 1, wherein said dielectric material includes organic field effect transistors.

8. The method of claim 1, wherein said functionalizing process is carried out at an ambient temperature.

9. The method of claim 1, wherein said amine-borane is part of an aromatic molecule, an aliphatic molecule, or a combination thereof.

10. The method of claim 1, wherein said amine-borane is part of a cyclic structure, a linear structure, a branched structure, or a combination thereof.

11. A semiconductor, conductor, or dielectric material, wherein surface of said material is functionalized by the method of claim 1.

12. A semiconductor, conductor, or dielectric material, wherein surface of said material is functionalized by a process of exposing said surface to a solution of an amine-borane carrying a functional moiety selected from the group consisting of alkene, alkyne, nitro, hydroxyl, thiol, cyano (nitrile), acetal, ester, amide, and alkoxysilane.

13. The semiconductor, conductor, or dielectric material of claim 12, wherein said functionalizing process further comprises a step of sonication.

14. The semiconductor, conductor, or dielectric material of claim 12, wherein said solution of an amine-borane is ethanol.

15. The semiconductor, conductor, or dielectric material of claim 12, wherein said functionalizing process is performed at an ambient temperature.

16. The semiconductor, conductor, or dielectric material of claim 12, wherein said amine-borane is part of an aromatic molecule, an aliphatic molecule, or a combination thereof.

17. The semiconductor, conductor, or dielectric material of claim 12, wherein said amine-borane is part of a cyclic structure, a linear structure, a branched structure, or a combination thereof.
